(19) United States
(12) Patent Application Publication
(10) Pub. No.: US 2003/0039152 A1
(43) Pub. Date: Feb. 27, 2003

(54) It flash memory recovery scheme for over-erasure

(76) Inventors: Danny Shum, Poughkeepsie, NY (US); Georg Tempel, Sterrebeek (BE); C. Ludwig, Langenbrueck (DE)

Correspondence Address: Thomas R. FitzGerald, Esq., 16 E. Main Street, Suite 210, Rochester, NY, 14614-1803, US

(21) Appl. No.: 09/771,808

(22) Filed: Jan. 29, 2001

Related U.S. Application Data
(60) Provisional application No. 60/179,234, filed on Jan. 31, 2000.

(51) Int. Cl. G11C 7/00

(52) U.S. Cl. 365/200

(57) ABSTRACT

A method is provided which uses a uniform electric potential across tunnel oxide, based on a uniform field to allow memory cell recovery from over-erasure.

This application claims priority under 35 USC 119 (e) of a provisional application entitled “Flash Memory Cell and the Method to Achieve Multiple Bits Per Cell and One Transistor Flash Memory Cell and the Method of Recovery From Over-Erasure” Application No. 60/179,234 filed Jan. 31, 2000 by inventors Danny Shum, Georg Tempel, and G. C. Ludwig

### BACKGROUND OF THE INVENTION

Electrical erasure of flash memories for one transistor flash memory cells are subject to erase threshold control problems. Electrical erase can continue beyond neutral level placing a net positive charge on the floating gate resulting a net negative threshold voltage. The negative threshold voltage can electrically short out a column of memory or increase leakage current of the same column, and result in reading false logic ones from the column during a read operation even if the selected cell is in a logic “0” state. Other cells may not be able to be programmed due to the current draw caused by an over-erased cell. The threshold voltage of the cell may change after electrical erasure due to coupling ratio and tunneling probability yielding a much wider threshold voltage distribution. Conventional flash memories have addressed this problem using several techniques: For instance, the verifiederase method see, V. N. Kynett et al., “A 90-ns One-Million Erase/Program Cycle 1-Mbit Flash Memory,” IEEE J. Solid-State Circuits, vol. SC-24, no. 10, pp. 1238-1243, 1989, results in a complicated erase algorithm and preprogramming of cells is required in case repeated cell programming results in leaky cells. The verified erase method controls the threshold voltage level of cells. However, the distribution of threshold voltages of all cells in a memory is usually Gaussian running typically from 4 volts down to 0 volts. Consequently, the time it takes to erase a bit can vary greatly among the cells. Reducing the spread of voltage of the distribution of threshold voltages provides a more overall uniform erase threshold voltage. The two step erase procedure addresses the need to shrink the spread of the erased Vt distribution. A flash EEPROM array is erased and a threshold voltage distribution of the erased flash EEPROM cells is converged to within a predetermined voltage range. In the first step, a conventional “edge” or “channel” electrically bulk erase procedure is accomplished by applying a high voltage to the control gate of the cell. Erase occurs according to a Fowler-Nordheim tunneling mechanism causing electrons to tunnel from the floating gate to the source (edge erase) or body (channel erase), resulting in cells with a relatively low threshold voltage. In the second step, the cell is programmed by applying a high voltage to the control gate (using Fowler-Nordheim tunneling) to converge the erased threshold voltage distribution of the array to within the predetermined voltage range. The drain, source and substrate of the iT flash transistor are grounded or presented with no bias across those regions. This grounded or non-biasing approach allows chip-wise or block-wise memory recovery from over erasure, but not column-wise recovery. Another method, the self-convergence erasing scheme is typically accomplished using channel hot carrier injection. (see S. Yamada et al., “A Self-Convergence Erasing Scheme for a Simple Stacked gate Flash EEPROM,” IEEE IEDM Tech. Dig., pp. 307-310, 1991. and K. Yoshikawa et al., “Comparison of Current Flash EEPROM Erasing Methods: Stability and How to Control,” IEEE IEDM Tech. Dig., p. 595, 1992). However, this is undesirable due to high current requirements.

### BRIEF DESCRIPTION OF THE DRAWINGS

FIG. 1 illustrates such a transistor 2, representative of an EEPROM cell from a column of transistors selected for a given operation, with gate electrode G, floating gate FG, bitline BL, source region S, and body region B.

FIG. 2 illustrates a schematic drawing of two columns of EEPROM flash memory cells from an array of memory cells.

FIG. 3 shows a schematic drawing of a memory cell from an unselected column.

Reference numbers and figures have been carried forward.

### DETAILED DESCRIPTION OF THE INVENTION

The recovery from over-erasure scheme according to the invention is accomplished by using a 1 transistor (1T) electrically-erasable programmable read only memory (EEPROM). FIG. 1 illustrates such a transistor 2, representative of an EEPROM cell from a column of transistors selected for a given operation, with fixed gate G, floating gate FG, bitline BL, source region S, and body region B. In connection with erasing a column of memory, the first step, for the case of an enhancement mode, n-channel transistor, gate G is brought to a strong negative high logic level, e.g. 6 volts, while the source region, body and bitline (connected to the drain of the transistor) are left floating. Erasure is accomplished from the floating gate to the channel region C of the transistor. To compensate for over-erasure, in order to recover the erased correct state for a transistor, gate G is brought to a strong high logic level, e.g. +6 volts while bitline BL and body region B are brought to a low level, e.g. −3 volts. The source region is left floating. Programming of the EEPROM cell is accomplished in a similar way, but with the bitline carrying the proper logic voltage level to be programmed into the cell.

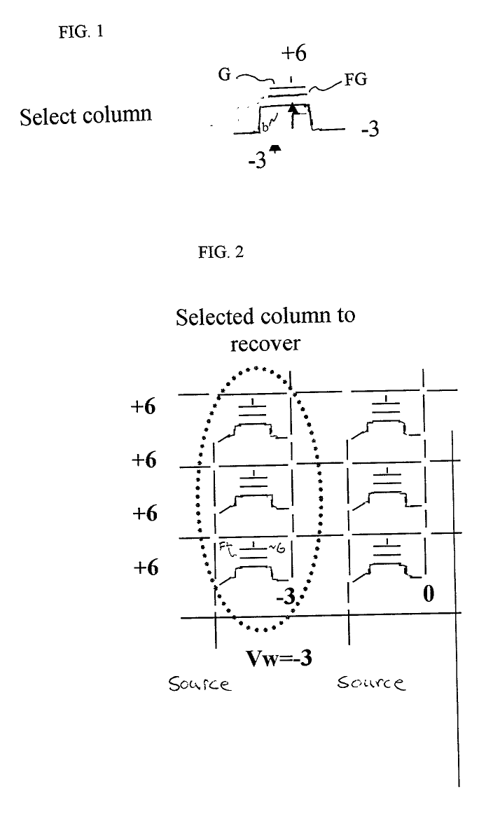

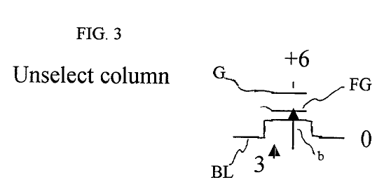

FIG. 2 illustrates a schematic drawing of two columns of EEPROM flash memory cells from an array of memory cells. In order to erase and recover from over erasure, a column of memory cells, the two step process described in the paragraph above is performed on the memory cells in a selected column. Unselected columns are biased according to the bias of a selected cell except that the bitline is raised in voltage. For instance, with reference to FIG. 3 which shows a schematic drawing of a memory cell from an unselected column, gate G is brought high, e.g. 6 volts, body B is at −3 volts, the source region is left floating and bitline BL is grounded (0 volts).

The flash memory recovery scheme can be applied chip-wise to all cells of the memory. In this instance, all cells are erased according to the afore described first step and all cells are biased according to the bias of a selected column as shown in FIG. 1.

The 2 step-recovery scheme of the invention uses a uniform electric potential across the tunnel oxide. Further the method allows low power with no GIDL leakage current, bulk mode and ensures a stable VT shift over time. The foregoing description is easily applied to p-channel devices by a change in polarity with floating nodes kept floating.

The invention can be implemented as an integrated circuit according to well known semiconductor fabrication methods.

Although the invention has been described in detail herein with reference to preferred embodiments and certain described alternatives, it is to be understood that this description is by way of example only, and it is not to be construed in a limiting sense. For instance p-channel EEPROMs according to the invention will be programmed with reverse polarities to those discussed, with supply voltage levels being substituted for ground. It is to be further understood that numerous changes in the details of the embodiments of the invention and additional embodiments of the invention, will be apparent to, and may be made by persons of ordinary skill in the art having reference to this description. It is contemplated that all such changes and additional embodiments are within the spirit and true scope of the invention as claimed below.

We claim:

1. A method of erasing an electrically erasable programmable read-only memory including a plurality of one transistor memory cells comprising:
a. placing a first voltage level on a fixed gate of a transistor of a selected one of said plurality of one transistor memory cells;
b. floating the voltage levels on the drain/source regions of said transistor;
c. and ensuring the recovery of a correct erased state by placing a voltage of reversed polarity to that placed on said fixed gate in step and;
d. placing a voltage on the source and body region of said transistor which is of a lesser magnitude and of a reversed polarity to that placed on said fixed gate in step c.
